(19) United States
(12) Patent Application Publication
(10) Pub. No.: US 2013/0136852 A1
(43) Pub. Date: May 30, 2013

(54) EDGE DETECTION

(71) Applicants: David Riedel, Dresden (DE); Stefan Liehr, Dresden (DE); Rina Ortega-Cagara, Mechanicville, NY (US)

(72) Inventors: David Riedel, Dresden (DE); Stefan Liehr, Dresden (DE); Rina Ortega-Cagara, Mechanicville, NY (US)

(73) Assignee: PLASTIC LOGIC LIMITED, Cambridge (GB)

(21) Appl. No.: 13/701,999

(22) PCT Filed: Jun. 3, 2011
(86) PCT No.: PCT/EP2011/059215

§ 371 Date: Feb. 12, 2013

(30) Foreign Application Priority Data
Jun. 4, 2010 (GB) 1009404.3

(51) Int. Cl. H05K 3/00; H05K 3/06

(52) U.S. Cl. CPC H05K 3/0011; H05K 3/06
USPC 427/58; 29/412; 29/846

(57) ABSTRACT

A technique comprising: forming a plurality of smaller substrates from one or more larger substrates by a reduction process according to which there is some possible variation size between the smaller substrates within a variation range; and, in advance of said reduction process, providing said one or more larger substrates with one or more detection marks whose size and location are selected such that after the reduction process each smaller substrate includes a portion of at least one of said one or more detection marks, said portion having one or more edges that coincide with at least a part of one or more edges of the smaller substrate whatever actual size the smaller substrate has within said variation range.

The present invention relates to a technique for detecting the edge of a substrate in the production of electronic apparatus, such as an electronically-controllable display apparatus.

The production of an electronic consumer apparatus typically involves processing the upper surface of a substrate before removing a perimeter portion of the substrate to create a trimmed substrate, bonding the trimmed substrate to a tape carrier package (TCP), and creating a seal between the opposing surfaces of the trimmed substrate and the TCP at an edge portion of the trimmed substrate to protect elements located closer to the centre of the trimmed substrate.

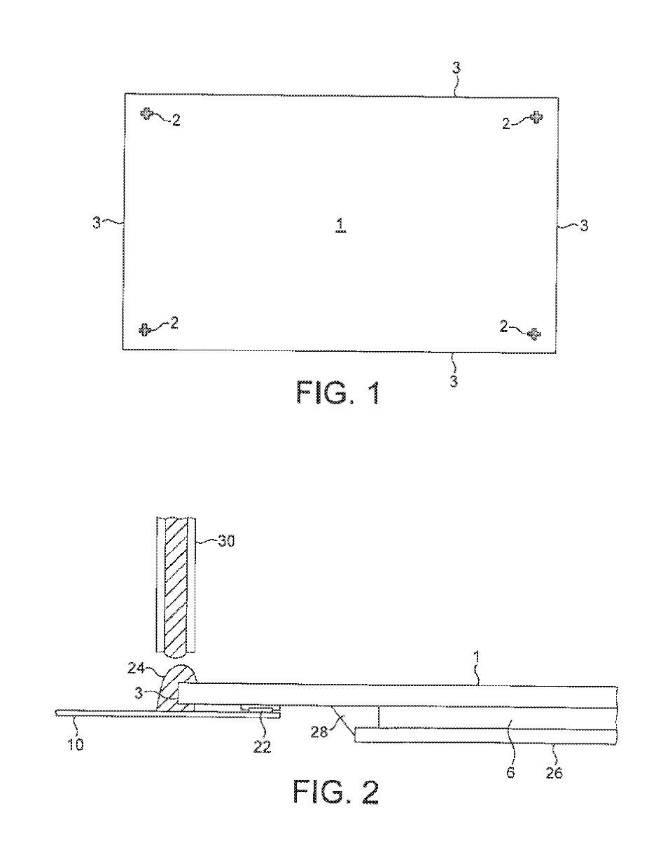

The provision of these seals has been carried out automatically by controlling the location of the deposition of a sealant material with reference to a set of alignment marks of the kind illustrated in FIG. 1, which are also used for other steps in the production process.

The inventors have found that the use of such alignment marks can result in the sealant material being deposited other than where it is required.

It is an aim of the present invention to provide an improved technique for automatically depositing sealant material at the edge of a trimmed substrate in the production of electronic apparatus, and to provide a technique for producing a trimmed substrate that facilitates the accurate deposition of sealant material at the edge of the trimmed substrate.

The present invention provides a method comprising: forming a plurality of smaller substrates from one or more larger substrates by a reduction process according to which there is some possible variation size between the smaller substrates within a variation range; and, in advance of said reduction process, providing said one or more larger substrates with one or more detection marks whose size and location are selected such that after the reduction process each smaller substrate includes a portion of at least one of said one or more detection marks, said portion having one or more edges that coincide with at least a part of one or more edges of the smaller substrate whatever actual size the smaller substrate has within said variation range.

In one embodiment, the method further comprises: forming each of said smaller substrates from a respective larger substrate by removing an edge portion of said larger substrate according to a removal process according to which there is some possible variation in the size of the removed edge portion between substrates within a variation range; and in advance of said removal process, providing each larger substrate with one or more detection marks whose size and location are selected such that a portion of each detection mark remains as part of the smaller substrate and has one or more edges that coincide with at least a part of one or more edges of the smaller substrate whatever actual size the removed edge portion has within said variation range.

In one embodiment, the size and the location of the detection marks are selected such that a portion of each detection mark remains as part of the smaller substrate at a corner of said smaller substrate, and has a pair of edges that coincide with at least a part of the pair of edges of the smaller substrate that define said corner, whatever the size of the removed edge portion within said variation range.

In one embodiment, the method further comprises: forming said detection marks as part of a patterned layer that also defines the conductive elements for one level of an array of electronic devices.

In one embodiment, the method further comprises: controlling the selective deposition of a sealant material at one or more edges of a substrate of an electronic apparatus on the basis of one or more detectable marks each having at least one edge that coincides with a part of at least one of said one or more edges of the substrate.

In one embodiment, each detectable mark is located at a corner of said substrate and has a pair of edges that coincide with a part of the respective pair of edges of said substrate that define said corner.

Hereunder is provided, by way of example only, a detailed description of an embodiment of the present invention, with reference to the accompanying drawings, in which:

FIG. 2 illustrates the deposition of sealant material to provide a mechanical seal between the edge portion of a trimmed substrate and a tape carrier package;

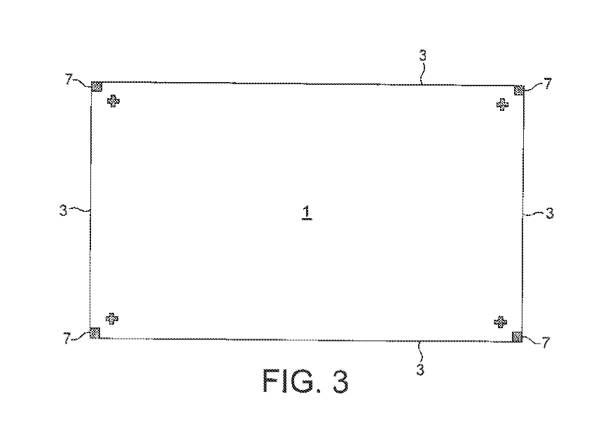

FIG. 3 illustrates the provision of detection marks at the corners of a trimmed substrate in accordance with an embodiment of the present invention;

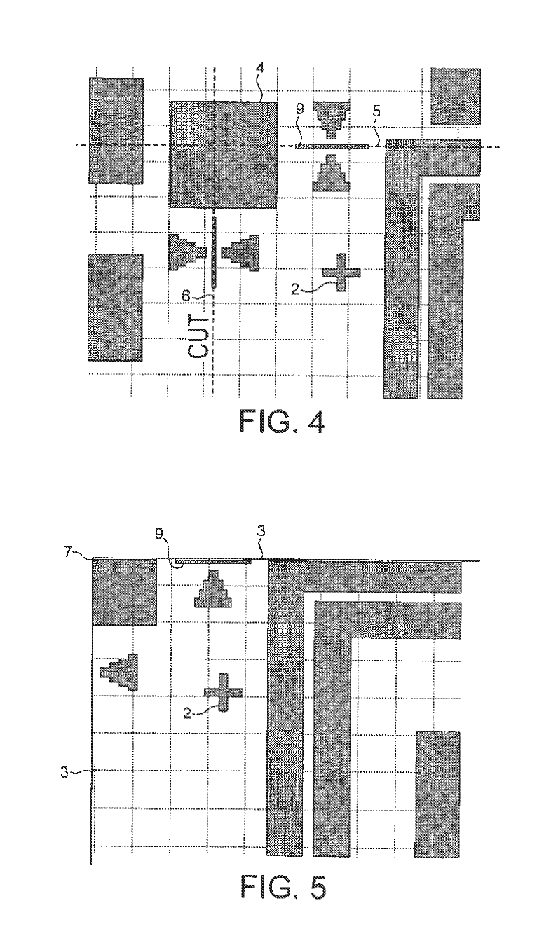

FIG. 4 illustrates an example of the provision of a new kind of detection mark on a corner section of an untrimmed substrate in accordance with an embodiment of the present invention; and

FIGS. 5, 6 and 7 show substrates after the trimming process and illustrate how the new detection mark of FIG. 4 has a portion aligned with the edges of a corner of a trimmed substrate, even if there is some variation in the substrate trimming process.

FIG. 2 illustrates the deposition of resin material 24 to create a mechanical seal between a substrate 1 and a tape carrier package 10. The substrate 1 is optically transparent, and, before the substrate trimming process, has been provided on its front side with an array of electronic transistor devices that function to control the operation of a display medium. The array of electronic transistor devices and the display medium are generally designated by block 6, and are protected by a top encapsulating layer 26 and an edge seal 28 between the substrate 1 and the top encapsulating layer 26. The top encapsulating layer 26 and the edge seals 28 provide environmental protection for the electronic transistor devices and display medium against humidity and moisture ingress.

The conductive elements (e.g. electrodes, addressing lines) at one level of the array of electronic transistor devices are defined by a patterned Ti/Au bilayer that is formed on a planarization layer over the substrate 1 by photolithographic and etching processes. As mentioned above, this patterned Ti/Au layer is formed before a perimeter portion of the substrate 1 is trimmed away. The patterned Ti/Au layer also defines marks which have no electronic function in the electronic transistor devices. These marks are illustrated in FIG. 4 for one corner section of the untrimmed substrate. The same set of marks is also provided at each of the other corner sections of the untrimmed substrate. The marks include: fiducial crosses 2; cut lines 9 for guiding the process of cutting away an perimeter portion of the substrate 1; and square marks 4, whose function is explained below.

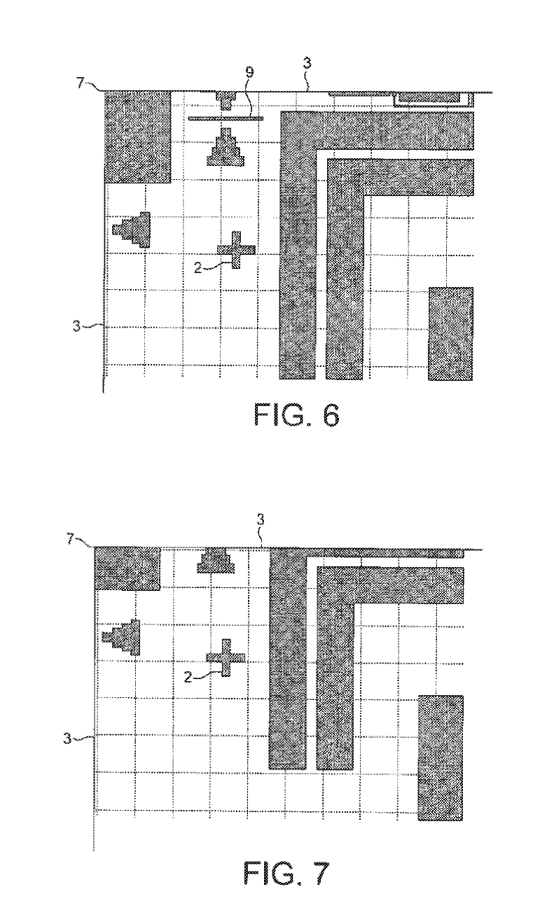

As mentioned above, after the processing of the upper surface of the substrate 1 is completed (i.e. after the formation of the array of electronic transistor devices, display medium, top encapsulating layer 26 and edge seals 28 etc. is completed), a perimeter portion of the substrate 1 is removed by making perpendicular cuts 5, 6, using for example, a laser, blade or water jet. The cutting process uses cut lines 9 as guide marks for the cuts. The nature of the cutting process is such that the actual location of the perpendicular cuts 5, 6 may vary between substrates. For example, the perpendicular cuts 5, 6 may coincide exactly with the cut lines 9 (as shown in FIGS. 4 and 5), or may deviate somewhat from the cut lines 9 (as shown in FIGS. 6 and 7) within an acceptable tolerance range.

Each of the square marks 4 mentioned above are sized and located such that wherever the perpendicular cuts 5, 6 are made within said tolerance range, a portion 7 of the square marks (which portion is hereafter referred to as a corner mark) remains at a respective corner of the trimmed substrate 1 with edges that are aligned with the two edges 3 of the trimmed substrate 1 that define the respective corner. FIG. 2 illustrates the resulting provision of the above-described corner marks 7 at each of the four corners of the trimmed substrate 1.

The front side of an edge portion of the trimmed substrate 1 is then bonded to a tape carrier package using anisotropic conductive film (ACF) bonds 22. Next, a resin 24 is deposited along the edge 3 of the trimmed substrate 1 so as to provide a mechanical seal between the trimmed substrate 1 and the tape carrier package 10, which mechanical seal serves to protect the ACF bonds 22. The resin deposition process is controlled using the corner marks 7 at the corners of the trimmed substrate as means by which an automatic recognition system identifies the edge 3 of the substrate. An optical detector (not shown) detects the corner marks 7, identifies the edge 3 of the substrate from the outer edges of the corner marks 7, and provides an input to a controller for adjusting the position of a resin deposition needle 30. The optical detector can detect the corner marks 7 from the rear side (backplane) of the trimmed substrate 1 because the substrate 1 is made of an optically transparent material.

The above described technique has the advantage that the precise location of the edges of the trimmed substrate can be detected accurately even if there is some variation in the cutting process and/or some distortion of the substrate during the processing of the substrate.

In order to facilitate the automated process of detecting the corner marks, the following measures are taken: (i) the square marks all have the same shape and size; (ii) the cutting process is designed such that the corner marks 7 all have either a square or rectangular shape, even if there is some variation in their size (this can be achieved by ensuring that the perpendicular cuts are always made at 90 degrees to each other); (iii) no similar shaped marks are provided on the substrate near the square marks that form the corner marks; and (iv) the cutting process is designed such that there is no chipping of the corner marks 7.

In addition to any modifications explicitly mentioned above, it will be evident to a person skilled in the art that various other modifications of the described embodiment may be made within the scope of the invention.

1. A method comprising: forming a plurality of smaller substrates from one or more larger substrates by a reduction process according to which there is some possible variation size between the smaller substrates within a variation range; and, in advance of said reduction process, providing said one or more larger substrates with one or more detection marks whose size and location are selected such that after the reduction process each smaller substrate includes a portion of at least one of said one or more detection marks, said portion having one or more edges that coincide with at least a part of one or more edges of the smaller substrate whatever actual size the smaller substrate has within said variation range.

2. A method according to claim 1, comprising: forming each of said smaller substrates from a respective larger substrate by removing an edge portion of said larger substrate according to a removal process according to which there is some possible variation in the size of the removed edge portion between substrates within a variation range; and in advance of said removal process, providing each larger substrate with one or more detection marks whose size and location are selected such that a portion of each detection mark remains as part of the smaller substrate and has one or more edges that coincide with at least a part of one or more edges of the smaller substrate whatever actual size the removed edge portion has within said variation range.

3. A method according to claim 2, wherein the size and the location of the detection marks are selected such that a portion of each detection mark remains as part of the smaller substrate at a corner of said smaller substrate, and has a pair of edges that coincide with at least a part of the pair of edges of the smaller substrate that define said corner, whatever the size of the removed edge portion within said variation range.

4. A method according to claim 1, comprising forming said detection marks as part of a patterned layer that also defines the conductive elements for one level of an array of electronic devices.

5. A method comprising: controlling the selective deposition of a sealant material at one or more edges of a substrate of an electronic apparatus on the basis of one or more detectable marks each having at least one edge that coincides with a part of at least one of said one or more edges of the substrate.

6. A method according to claim 5, wherein each detectable mark is located at a corner of said substrate and has a pair of edges that coincide with a part of the respective pair of edges of said substrate that define said corner.
